(19) United States
(12) Patent Application Publication
(10) Pub. No.: US 2025/0259931 A1
(43) Pub. Date: Aug. 14, 2025

(54) GRADUATED ETCH STOP FOR METALLIZATION LAYERS OF INTEGRATED CIRCUITS

(71) Applicant: Intel Corporation, Santa Clara, CA (US)

(72) Inventors: Yung-Jih Yang, Beaverton, OR (US); Danielle Casillas, Portland, OR (US); Ahmad Al-Kukhun, Beaverton, OR (US)

(73) Assignee: Intel Corporation, Santa Clara, CA (US)

(21) Appl. No.: 18/436,457

(22) Filed: Feb. 8, 2024

(51) Int. Cl. H01L 23/532; H01L 21/768; H01L 23/522

(52) U.S. Cl. CPC H01L 23/53295; H01L 21/76834; H01L 23/5226

(57) ABSTRACT

A graduated etch stop layer is included within a metallization stack of an integrated circuit device. The graduated etch stop layer has a higher concentration of a dopant at an upper portion of the layer than at a lower portion of the layer. The dopant may be oxygen, which reduces capacitance between metal lines compared to other etch stop materials (e.g., silicon carbide). The graduated etch stop layer may be produced in a single plasma processing flow, with a first set of parameters (e.g., a first set of precursors, first temperature, first power) in a first stage to deposit an initial etch stop material, and a second set of parameters (e.g., a second set of precursors, a second temperature, a second power) in a second stage of the process flow to dope the etch stop material.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each IC die, including devices and interconnects, becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1C illustrate different cross sections of an IC device having a device layer and multiple metal layers, according to some embodiments of the present disclosure.

FIG. 2 is a flow diagram of a process for forming a graduated etch stop layer in a metallization stack, according to some embodiments of the present disclosure.

FIG. 3 is a cross-section of metal lines within a metal layer, according to some embodiments of the present disclosure.

FIG. 4 is a cross-section illustrating deposition of an etch stop material, according to some embodiments of the present disclosure.

FIG. 5 is a cross-section illustrating doping of the deposited etch stop material, according to some embodiments of the present disclosure.

FIG. 6 is an enlarged view of a portion of FIG. 5, according to some embodiments of the present disclosure.

FIG. 7 is a cross-section illustrating additional layers of the metallization stack formed over the etch stop layer, according to some embodiments of the present disclosure.

FIG. 8 is an enlarged view of a portion of FIG. 7, according to some embodiments of the present disclosure.

FIGS. 9A and 9B are top views of a wafer and dies that include one or more metal layers with at least one graduated etch stop layer in accordance with any of the embodiments disclosed herein.

FIG. 10 is a cross-sectional side view of an IC device that may include one or more metal layers with at least one graduated etch stop layer in accordance with any of the embodiments disclosed herein.

FIG. 11 is a cross-sectional side view of an IC device assembly that may include metal layers with at least one graduated etch stop layer in accordance with any of the embodiments disclosed herein.

FIG. 12 is a block diagram of an example computing device that may include one or more metal layers with at least one graduated etch stop layer in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

An IC device includes various circuit elements, such as transistors and capacitors, coupled together by metal interconnects. The circuit elements and metal interconnects may be formed in different layers. In particular, one or more layers of an IC device in which transistors and other IC components are implemented may be referred to as a “transistor layer” or “device layer”. Layers with conductive interconnects for providing electrical connectivity (e.g., in terms of signals and power) to the transistors and/or other devices of the transistor layer of the IC device may be referred to as a “metal layer,” “metallization layer,” or “interconnect layer”. For example, the device layer may be a front-end-of-line (FEOL) layer, while the metal layers may be back-end-of-line (BEOL) layers formed over the FEOL layer. In general, the transistor layer and the metal layers may be provided in any layers of an IC device as long as they are in different planes (e.g., at different distances from) a support structure (e.g., a die, a chip, a substrate, a carrier substrate, or a package substrate) of the IC device, or some other reference plane.

Typically, an IC device includes a metallization stack, which is a collection of several metal layers, stacked above one another, in which different interconnects are provided. The interconnects include electrically conductive trenches, also referred to as lines, which provide connectivity across the layer, and electrically conductive vias (or, simply, “vias”) that provide electrical connectivity between different layers. In general, the term “trench” or “line” may be used to describe an electrically conductive element isolated by an insulator material (e.g., an insulator material typically comprising a low-k dielectric) that is provided in a plane parallel to the plane of an IC die/chip or a support structure over which an IC structure is provided, while the term “via” may be used to describe an electrically conductive element that interconnects two or more trenches of different levels of a metallization stack, or a component of the transistor layer and one or more trenches of a metallization layer. To that end, a via may be provided substantially perpendicularly to the plane of an IC die/chip or a support structure over which an IC structure is provided, and the via may interconnect two trenches in adjacent levels, two trenches in not adjacent levels, and/or a component of a transistor layer and a trench in adjacent or not adjacent layers. Sometimes, trenches and vias may be referred to as “metal trenches/tracks/lines/traces” and “metal vias”, respectively, to highlight the fact that these elements include electrically conductive materials such as, but not limited to, metals. Together, trenches and vias may be referred to as “interconnects,” “interconnect structures,” or “conductive structures,” where these terms may be used to describe any element formed of an electrically conductive material for providing electrical connectivity to/from one or more components associated with an IC or/and between various such components.

As noted above, there is a drive to reduce the feature size and increase density on IC chips. As transistor sizes decrease, the metal lines in metal layers formed over the device layer are correspondingly denser. For example, pitches between adjacent metal lines are reduced so that connections to and between the transistors can be provided in the metallization layers. However, tight, high-aspect ratio metal lines are subject to capacitance between the metal lines, which reduces overall device performance. Metal lines between nearby layers, particularly when the metal lines extend in the same direction (e.g., M0 and M2 layers having lines extending parallel to each other), may also be subject to capacitance; the capacitance may be greater between relatively lower layers (e.g., M0 and M2, or M1 and M3) where the layers are thinner, and thus metal lines are closer together.

Typically, dielectric materials are included in the metallization stack, filling areas between metal structures. In addition, etch stop layers may be included within and/or between layers of the metallization stack. For example, an etch stop may be deposited over a layer with lines in it, to protect the underlying layer during a subsequent via formation step.

Capacitance is proportional to the dielectric constant or relative permittivity of the material between parallel plates, e.g., two parallel metal lines in a metallization stack, with materials having a higher dielectric constant resulting in greater capacitance. Reducing the dielectric constant between metal lines reduces the capacitance between metal lines. Silicon dioxide is a common dielectric material that has a dielectric constant of 3.9. Materials typically used for etch stop materials, such as silicon carbide and silicon nitride, have a higher dielectric constant (e.g., 5.7 or greater); this can lead to a high capacitance between metal lines on either side of the etch stop.

Doping the etch stop material, e.g., by adding oxygen to it, can reduce the dielectric constant, and thus reduce capacitance between metal lines. As disclosed herein, the initial etch stop deposition (e.g., silicon and carbon deposition) and doping process may be performed in a single process flow, e.g., within the same chamber and a with continuous plasma. During the process flow, a first set of parameters (e.g., gas flows into the chamber, high power, etc.) are used to deposit the initial etch stop material, and a second set of parameters (e.g., different gas flows, a lower power, etc.) are used to dope the initial etch stop material. In some cases, the process flow may further include a densification step to increase density of the doped etch stop material. The result of this single deposition and doping process is a graduated etch stop layer, in which the dopant concentration is higher towards the top of the layer, and lower towards the bottom of the layer. Specifically, the oxygen dopant may replace some of the carbon in the etch stop layer; the oxygen is concentrated towards the upper surface of the etch stop layer, which is exposed during the doping stage.

Using a single process flow to both deposit and dope the etch stop layer reduces defects in the resulting etch stop layer compared to a process in which deposition and doping are performed in separate process flows. Using a single process flow also improves fabrication efficiency. Furthermore, the resulting etch stop layer has improved performance (e.g., lower dielectric constant, reduction of detects) compared to a process in which the main etch stop material (e.g., silicon and carbon) and dopant (e.g., oxygen) are deposited simultaneously, resulting in a homogenous layer, with the dopant evenly distributed throughout the layer.

The metal layers with graduated etch stop materials described herein may be implemented in combination with one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

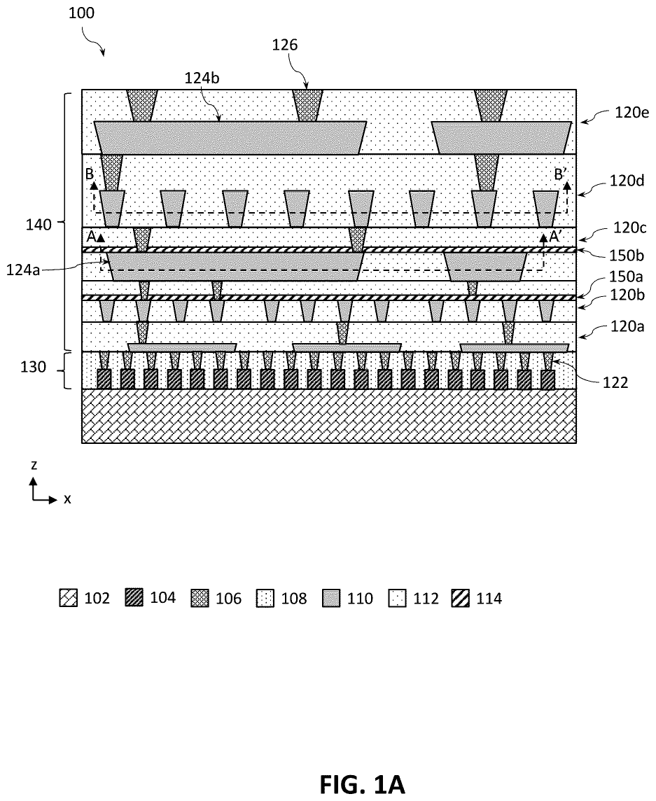

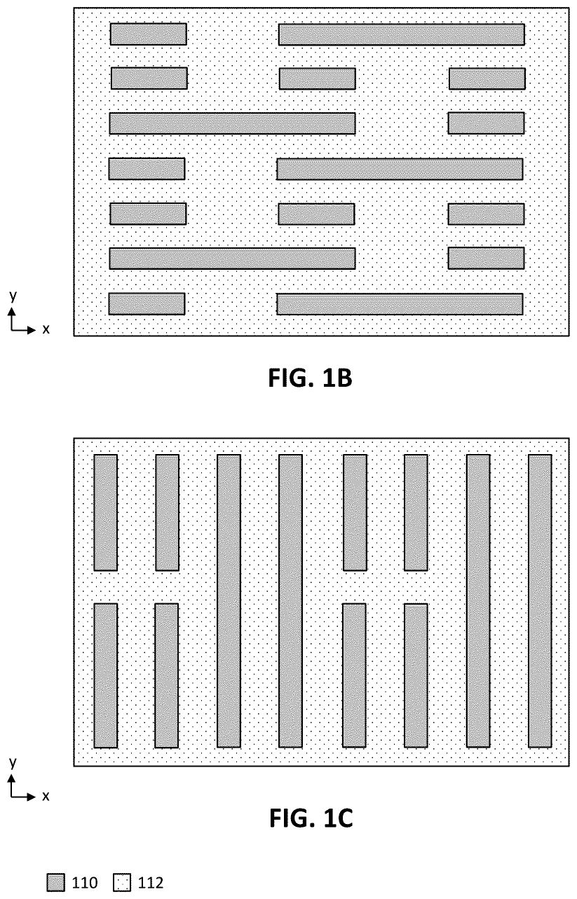

For convenience, if a collection of drawings designated with different letters are present, e.g., FIGS. 1A-1C, such a collection may be referred to herein without the letters, e.g., as “FIG. 1.”

Example IC Device with Device Layer and Metal Layers

FIGS. 1A-1C illustrate different cross sections of an IC device 100 having a device layer and multiple metal layers, according to some embodiments of the present disclosure. The etch stop layer described herein may be included in and/or between more of the metal layers. FIG. 1A provides a first cross-section in an x-z plane. FIGS. 1B and 1C provide two cross-sections through the x-y plane. FIG. 1B is a cross-section through the plane AA′ in FIG. 1A, and FIG. 1C is a cross-section through the plane BB′ in FIG. 1A.

A number of elements referred to in the description of FIGS. 1A-1C and 3-8 with reference numerals are illustrated in these figures with different patterns, with a legend showing the correspondence between the reference numerals and patterns being provided at the bottom of the drawing pages. For example, the legend in FIG. 1A illustrates that FIG. 1A uses different patterns to show a support structure 102, logic devices 104, a first conductive material 106, a first dielectric material 108, a second conductive material 110, a second dielectric material 112, and an etch stop material 114.

FIG. 1A illustrates cross sections of a device layer 130 and a metallization stack 140. The device layer 130 is over a support structure 102. In this example, the device layer 130 includes logic devices 104, e.g., transistors. In some embodiments, the logic devices 104, or a portion of the logic devices 104, are logic transistors in a compute logic layer or compute logic region. In some embodiments, the logic devices 104, or a portion of the logic devices, are access transistors in a memory layer, e.g., transistors that provide access to capacitor-based memory. In some embodiments, the logic devices 104 may provide transistor-based memory, such as static random-access memory (SRAM), which uses transistors arranged as latches, also referred to as flip-flops, to store data. In some embodiments, the device layer 130 and/or additional layers above or below the device layer 130 may include additional or alternative types of devices, such as capacitors, inductors, waveguides, etc.

The logic devices 104 may include a wide variety of configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors. As shown in FIG. 1A, at least a portion of the logic devices 104 may be coupled to interconnect structures in the metallization stack 140. For example, the logic devices 104 may be semiconductor devices (e.g., transistors) coupled to contacts formed from the first conductive material 106 (e.g., source, drain, and/or gate contacts). The via 122 is an example of a contact to a logic device 104.

The metallization stack 140 includes multiple metal layers 120a-120e, where 120a is the lowermost metal layer over the device layer 130, and the metal layer 120e is the uppermost metal layer. While five metal layers 120a, 120b, 120c, 120d, and 120e are illustrated in FIG. 1A, an IC device may have fewer or more metal layers, e.g., up to 10 metal layers, up to 15 metal layers, or more. In addition, while metal layers 120 are on one side of the device layer 130, in other embodiments, metal layers may be included on both sides of the device layer 130, e.g., on the front side and the back side.

Each metal layer 120 includes conductive structures, including metal lines or trenches (e.g., the lines 124a and 124b) formed from the second conductive material 110 and vias (e.g., the via 126) formed from the first conductive material 106. In general, interconnect structures, e.g., vias and metal lines, are referred to herein as conductive structures. While FIG. 1 illustrates a first conductive material 106 for the vias and a second conductive material 110 for the metal lines, at each metal layer, any suitable conductive material may be used. For example, in a given layer, the same conductive material may be used for both metal lines and vias. As another example, in different layers, different materials may be used for the metal lines and/or vias, e.g., ruthenium may be included in the metal lines in the metal layer 120a, while copper is included in the metal lines in the metal layer 120d. In various embodiments, conductive structures may include multiple conductive materials, e.g., a first metal as a liner, and a second metal as a fill.

The logic devices 104 are surrounded by a first dielectric material 108 in the device layer 130. The metal lines and vias in the metal layers 120a-120e are surrounded by a second dielectric material 112. In some embodiments, the dielectric materials 108 and 112 may be the same. In some embodiments, different dielectric materials may be included in different ones of the metal layers, e.g., the metal layer 120a may include a different dielectric material from the metal layer 120d. In some embodiments, multiple dielectric materials may be present in a given layer.

More generally, the dielectric materials 108 and 112 may include low-k or high-k dielectrics including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of dielectric materials include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

In addition, the conductive materials 106 and 110 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, conductive materials 106 and 110 may include one or more electrically conductive alloys, oxides, or carbides of one or more metals. The conductive materials 106 and 110 may form conductive pathways to route power, ground, and/or signals to/from various components of the logic layer 130. The arrangement of the conductive materials 106 and 110 in FIG. 1 is merely illustrative, and the conductive pathways formed by the conductive materials 106 and 110 may be connected to one another in any suitable manner.

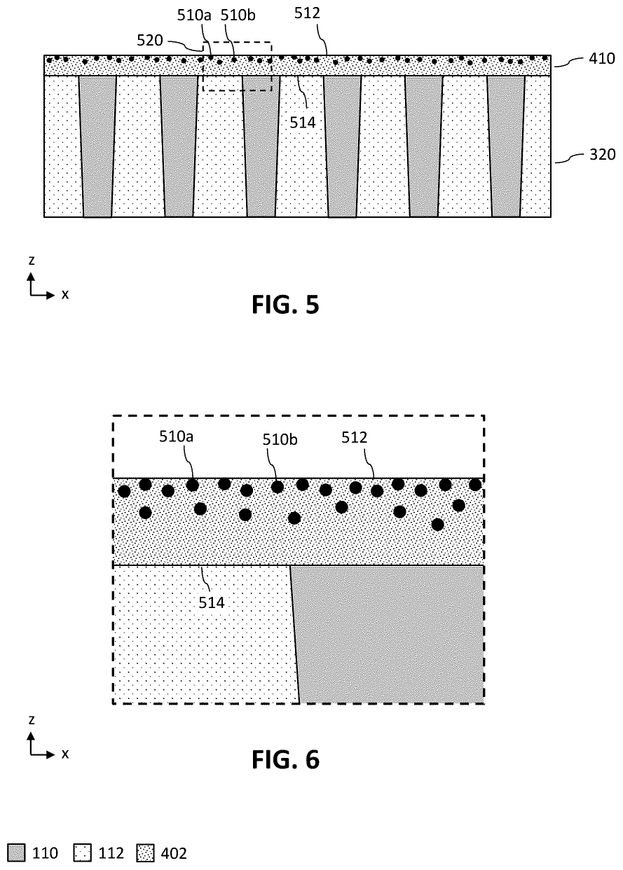

One or more of the metal layers 120 may include an etch stop layer 150. In this example, the metal layers 120b and 120c (e.g., metal layers M1 and M2) each include a respective etch stop layer 150a and 150b. While two etch stop layers 150a and 150b are illustrated in FIG. 1A, in other examples, additional metal layers, fewer metal layers, and/or different metal layers may include an etch stop layer 150. In general, an etch stop layer 150 may be included in lower metallization layers, e.g., one or more of the first five layers (referred to as M0 to M4) over the device layer 130, or one or more of the first eight layers (referred to as M0 or M7) over the device layer 130, for example. While the etch stop layers 150a and 150b are illustrated as being within a metal layer (e.g., above a trench and around the bottom of a via), in some cases, an etch stop layer 150 may be included between two metal layers, e.g., between layers 120a and 120b, between layers 120b and 120c, etc. The etch stop layer 150 includes an etch stop material 114, which may include a main etch stop material and a dopant. The dopant may be concentrated in an upper portion of each etch stop layer 150, as described further below. The etch stop layers illustrated in FIGS. 5-8 are examples of the etch stop layer 150.

The support structure 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the support structure 102 may be formed are described here, any material that may serve as a foundation upon which an IC device as described herein may be built falls within the spirit and scope of the present disclosure.

FIGS. 1B and 1C illustrate cross-sections through two example metal layers 120c and 120d. The metal lines in a given metal layer are generally elongated structures that extend primarily in one direction within the metal layer. Typically, this direction is substantially parallel to the or perpendicular to the arrangement of the logic devices in the device layer 130, and is either perpendicular or parallel to different edges of the support structure 102, in particular, being either perpendicular or parallel to different edges of the front face or the back face of the support structure. At different metal layers 120, the metal lines may extend in different directions. For example, in the metal layer 120c, the metal lines extend in the x-direction in the coordinate system shown in FIG. 1, as illustrated in FIG. 1B. In the metal layer 120d, the metal lines extend in the y-direction in the coordinate system shown in FIG. 1 (i.e., perpendicular to the metal lines in metal layer 120c), as illustrated in FIG. 1C.

The etch stop layer, where present in a metal layer, generally extends in parallel to the metal lines, and may be arranged between a pair of metal lines in different metal layers. For example, the line 124b in the metal layer 120e extends in the x-direction, and the line 124a in the metal layer 120c also extends in the x-direction. The etch stop layer 150b is between the two lines 124a and 124b, and may reduce capacitance between the lines 124a and 124b, which extend in parallel to each other. The etch stop layers may also reduce capacitance between lines that extend in perpendicular directions, e.g., the etch stop layer 150b may reduce capacitance between the line 124a and the lines in the metal layer 120d that are over the line 124a.

### Example Process for Forming a Graduated Etch Stop Layer

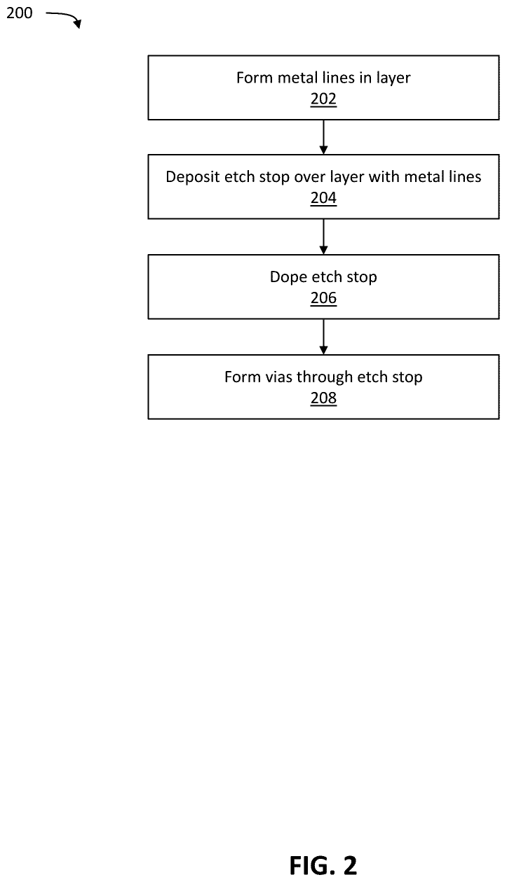

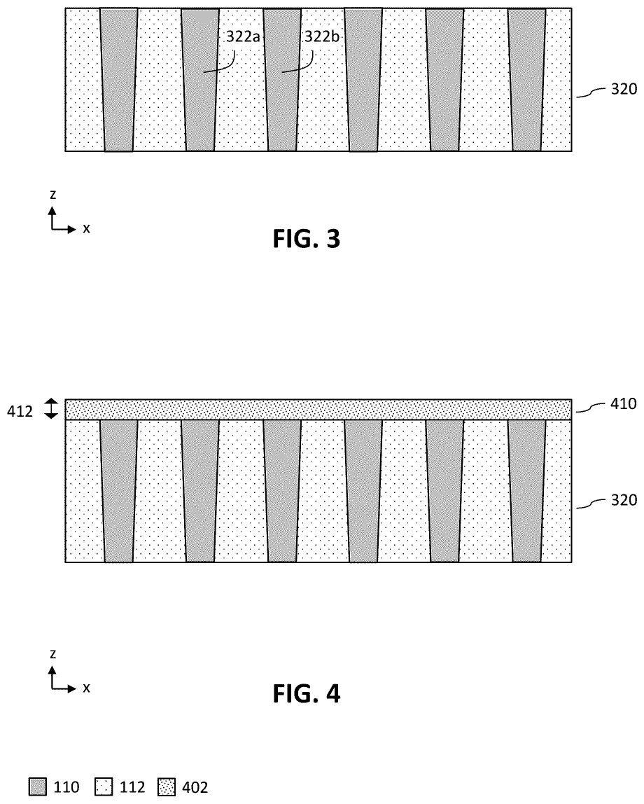

FIG. 2 is a flow diagram of a process for fabricating a graduated etch stop layer in a metallization stack, according to some embodiments of the present disclosure. For example, the processing method 200 shown in FIG. 2 may be used to fabricate the etch stop layers 150a and 150b of FIG. 1A. FIGS. 3-8 illustrate various steps in the processing method 200 of FIG. 2, according to some embodiments of the present disclosure. In general, the processing method 200 is performed across a wafer, with the etch stop layer formed across much or all of the wafer. Portions of the etch stop layer may be removed during subsequent processing steps, e.g., during via formation and/or other fabrication processes. In addition, the processing method 200 may be performed multiple times on a wafer, e.g., in different metal layers (e.g., the metal layers 120b and 120c of FIG. 1). FIGS. 3-8 illustrate cross-sections of processing steps across a span of several metal lines in one example metal layer. Additional steps may be performed before, during, and/or after the process 200 to produce an IC device that includes one or more of the graduated etch stop layers described herein.

At 202, a process for forming metal lines is performed. The metal lines may be in single layer, e.g., one of the metal layers 120 of the metallization stack 140. The metal lines may be formed using an additive process or a subtractive process. In a subtractive process, a material is deposited or transferred onto an area (e.g., a wafer or die), and portions of the material are removed, such that the remaining material has a desired pattern. For example, to form metal lines using a subtractive process, a metal is deposited across a region, and a resist material is deposited over top of the metal. The resist may be patterned based on a design for a particular pattern for the metal lines. The resist may be patterned using any known technique, e.g., by lithographically patterning the resist, and etching portions of the resist. After patterning the resist, portions of the metal that are exposed by the patterned resist are removed using an etching process. The remaining resist may removed, or removed at a later time.

In an additive process, a first material (e.g., a dielectric material) is deposited, and portions of the first material are removed. For example, the first material may be deposited in a layer, and a resist material may be deposited over the first material. The resist material is patterned based on a design for a particular pattern for the metal lines (e.g., using lithography) and then portions of the resist and the underlying first material are etched. Alternatively, the first material may itself be a photosensitive material that is directly patterned and etched. A metal for forming the metal lines is then deposited into the areas where the first material had been removed.

FIG. 3 is a cross-section of metal lines within a metal layer, according to some embodiments of the present disclosure. In this example, a series of metal lines 322, including adjacent metal lines 322a and 322b, are formed in a layer 320. The metal lines 322 include the second conductive material 110. The layer 320 further includes the second dielectric material 112 between the metal lines 322. The layer 320 may correspond to one of the metal layers 120 of FIG. 1. For example, the layer 320 may be the lower portion of the metal layer 120b, and FIGS. 3-8 illustrate the formation of the etch stop layer 150a and the vias in the metal layer 120b.

In the layer 320, the metal lines extend in the y-direction (i.e., into or out of the page) in the coordinate system shown. The metal lines 322 may have a width (measured in the x-direction in the coordinate system shown) of, for example, between 1 and 3 nanometers (nm), between 2 and 5 nm, between 5 and 10 nm, between 10 and 20 nm, between 20 and 30 nanometers, between 30 and 50 nanometers, or a different width or range of widths. In some embodiments, different metal lines 322 may have different widths. The metal lines 322 may have a height in the z-direction of, e.g., 10-100 nm. As illustrated in FIG. 1, in general, at higher layers (e.g., farther from the device layer 130), the metal lines have greater heights and widths than at lower layers (e.g., layers closer to the device layer 130).

The metal lines 322 are arranged at a pitch, where pitch refers to the center-to-center distance between closest adjacent structures, e.g., a center-to-center distance between the metal lines 322a and 322b. The pitch may be, for example, less than 50 nm or less than 20 nm, e.g., between 5 and 10 nm, between 10 and 20 nm, between 20 and 40 nanometers, between 30 and 50 nanometers, or a different pitch or range of pitches. In some embodiments, different sets of metal lines 322 may be arranged at different pitches. As illustrated in FIG. 1, in general, at higher layers (e.g., farther from the device layer 130), the metal lines have greater pitches than at lower layers (e.g., layers closer to the device layer 130).

In this example, the metal lines 322 taper (i.e., become increasingly narrow) in a downward direction in the cross-section and orientation shown in FIG. 3. For example, a width of the metal line 322a at a lower portion of the metal line 322a (e.g., along an lower surface of the layer 320 under the metal line 322a) is narrower than a width 332 of the metal line 322b at the upper portion of the metal line 322a (e.g., along an upper surface of the layer 320). This may indicate that the metal lines 322 were formed using additive processing. By contrast, when subtractive processing is used, the metal lines 322 may taper (i.e., become increasingly narrow) in an upward direction in the cross-section and orientation shown in FIG. 3.

Returning to FIG. 2, at 204, an etch stop material is deposited over the layer 320 with the metal lines 322. The etch stop material may include carbon and silicon, e.g., silicon carbide (SiC). In other examples, the etch stop material may include additional or different materials, e.g., the etch stop material may include nitrogen. The etch stop material may be deposited in a plasma deposition process e.g., plasma enhanced chemical vapor deposition (PECVD). In chemical vapor deposition (CVD) processes, gaseous precursors are introduced into a deposition chamber; the precursors react with an exposed surface, leading to the formation of thin layers, or film, over the surface. The etch stop material may have a crystal structure, e.g., silicon and carbon atoms may be arranged in a hexagonal lattice. In PECVD, a plasma environment is used to enhance the deposition process. For example, the plasma can cause dissociation of precursor molecules and the creation of large quantities of free radicals. Furthermore, the plasma can expose the deposited etch stop material to energetic ion bombardment during deposition, which can lead to increases in the density of the film and help remove contaminants, thus improving the film's electrical and mechanical properties.

FIG. 4 is a cross-section illustrating deposition of an etch stop material, according to some embodiments of the present disclosure. An initial etch stop material 402 has been deposited over the layer 320, including over the tops of the metal lines 322. The initial etch stop material 402 forms an etch stop layer 410. The etch stop layer 410 may be deposited in a plasma environment, e.g., using the PECVD process described above. The initial etch stop material 402 may include silicon and carbon, as described above. The etch stop layer 410 may have a thickness 412 (measured in the z-direction) of, e.g., less than 20 nanometers, between 1 and 15 nanometers, between 1 and 5 nanometers, between 5 and 15 nanometers, or within some other range.

Returning to FIG. 2, at 206, the etch stop material is doped. For example, a dopant may be introduced to the PECVD chamber. In some embodiments, the same plasma used in the etch stop deposition process is used for the doping process; in other words, the etch stop deposition and doping are two stages of a single process flow, with the chemistry (e.g., at least one of the gaseous precursors) and, in some cases, other deposition parameters (e.g., power, pressure, and/or temperature) changing between the etch stop deposition stage and the doping stage of the process flow. In one particular example, a lower power is used during the doping stage than the etch stop deposition stage. The etch stop material may be doped with oxygen, which lowers the dielectric constant of the etch stop material. For example, during the doping stage, carbon dioxide (CO₂) or nitrous oxide (N₂O) may be introduced to the deposition chamber. The oxygen in the precursor material may react with the silicon carbide etch stop layer, replacing some of the carbon atoms in the etch stop layer with oxygen atoms. Because the doping stage is performed after the etch stop material was deposited in the initial deposition stage, the dopant (e.g., the oxygen atoms) are concentrated near the exposed surface of the etch stop layer. This results in a graduated etch stop layer, with a higher concentration of carbon (and correspondingly lower concentration of oxygen) near the bottom of the layer, and a higher concentration of oxygen (and correspondingly lower concentration of carbon) near the top of the layer.

FIG. 5 is a cross-section illustrating doping of the deposited etch stop material, according to some embodiments of the present disclosure. Oxygen atoms 510, including oxygen atoms 510a and 510b, are represented as black dots in the etch stop layer 410. As shown in FIG. 5, the oxygen atoms 510 are concentrated near the top surface 512 of the etch stop layer 410. Thus, after doping, the material composition of the etch stop layer 410 is graduated, so that at different heights along the etch stop layer 410, there are different concentrations of the oxygen atoms 510 (and correspondingly different concentrations of carbon atoms, as noted above).

FIG. 6 is an enlarged view of a portion 520 of FIG. 5. FIG. 6 shows example oxygen atoms 510, including oxygen atoms 510a and 510b, in the upper portion of the etch stop layer 410. As noted above, the oxygen atoms 510 replace carbon atoms in the crystal structure. The crystal structure, and the carbon and silicon atoms, are not specifically shown in FIGS. 5 and 6. In the etch stop layer 410, the silicon and carbon atoms may form a regular crystal structure across the layer, e.g., a hexagonal structure. When doped, the oxygen atoms 510 replace a portion of the carbon atoms in the crystal structure, and specifically, the oxygen atoms 510 replace more carbon atoms near the exposed face of the etch stop layer 410. Thus, after doping, at an upper portion of the etch stop layer 410 (e.g., along the top surface 512 of the etch stop layer 410), the concentration of carbon may be lower, and the concentration of oxygen may be higher, than at a lower portion of the etch stop layer 410 (e.g., along the bottom surface 514 of the etch stop layer 410).

The oxygen doping may generally decrease the density of the etch stop layer 410. Oxygen has a greater size and lower atomic density than carbon; due to the larger atomic size of oxygen, when oxygen replaces carbon in a crystal lattice, this increases overall material volume of the crystal structure without contributing significantly to the mass of the etch stop layer 410. Decreasing the density of the etch stop layer 410 may decrease its dielectric constant.

In some embodiments, after doping, the etch stop layer 410 has a dielectric constant that is less than the dielectric constant of silicon carbide. For example, after doping, the dielectric constant of the etch stop layer 410 may be less than 5.5, less than 5.3, less than 5.1, less than 5.0, between 4.5 and 5.5, between 4.9 and 5.1, or within some other range of values.

In some examples, a densification process may be performed on the etch stop layer after the doping step. In some embodiments, the same plasma used in the etch stop deposition process and the doping process are used for the densification process; in other words, the etch stop deposition, doping, and densification are three stages of a single process flow, with the chemistry and/or other deposition parameters (e.g., power, pressure, and/or temperature) changing between the three stages of the process flow. For example, during the densification stage, the plasma may interact with the etch stop layer 410 to remove impurities, thus increasing the density of the etch stop layer 410. As another example, an annealing process (which may be an annealing stage performed in during the same process flow as the deposition and doping stages) may densify the etch stop layer 410. In some embodiments, densification of the etch stop layer 410 may be concurrent to the deposition and/or doping stages. For example, the deposition parameters of the PECVD process may result in densification of the initial etch stop material 402, as described above.

Returning to FIG. 2, at 208, a process for forming vias through the doped etch stop material is performed. For example, an additional dielectric layer is deposited over the etch stop layer 410, and portions of the dielectric layer and the etch stop layer 410 are removed. A conductive material, such as the first conductive material 106, is deposited into the regions where the dielectric layer and the etch stop layer 410 were removed, forming vias that extend through the etch stop layer 410; at least a portion of the vias contact portions of the metal lines below the etch stop layer 410. A set of metal lines, the etch stop layer 410, and a set of vias may together form one metal layer. One or more additional metal layers, each of which may include metal lines, an etch stop layer similar to the etch stop layer 410, and vias, may be formed over the completed metal layer to realize a metallization stack.

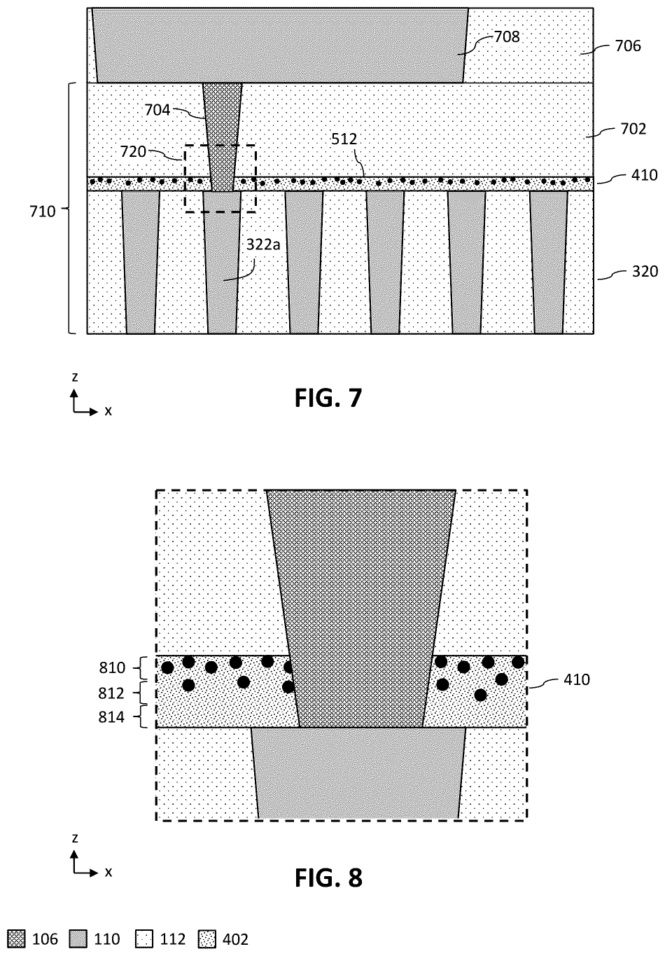

FIG. 7 is a cross-section illustrating additional layers of the metallization stack formed over the etch stop layer, according to some embodiments of the present disclosure. A dielectric layer 702 is deposited over the upper surface 512 of the etch stop layer 410. The dielectric layer 702 may include any suitable dielectric material for forming vias, e.g., the second dielectric material 112 described with respect to FIG. 1. The dielectric layer 702 may have a different composition from the dielectric material in the layer 320 or the same composition. A via 704 extends through the dielectric layer 702 and the etch stop layer 410. For example, a via hole may be etched in the dielectric layer 702 and the etch stop layer 410 using a lithographic process, and the via hole may be filled with first conductive material 106 to form the via 704. In this example, the via 704 is aligned to the metal line 322a; a lower surface of the via 704 is in direct contact with an upper surface of the metal line 322a, thus electrically coupling the via 704 to the metal line 322a.

The layer 320, the etch stop layer 410, and the dielectric layer 702 with the via 704 form a metal layer 710, e.g., one of the metal layers 120b or 120c of FIG. 1. While one via 704 is shown in FIG. 7, it should be understood that additional vias may be included in the metal layer 710, e.g., at different positions in the x-direction and/or y-direction in the coordinate system shown.

In addition to the metal layer 710, a portion of an additional metal layer over the metal layer 710 is illustrated. The next metal layer includes a dielectric layer 706 with a metal line 708 formed therein. The metal line 708 extends primarily in the y-direction, e.g., in a perpendicular direction to the metal lines 322. In this example, an upper surface of the via 704 is in direct contact with a lower surface of the metal line 708, thus electrically coupling the metal line 708 to the metal line 322a.

FIG. 8 is an enlarged view of a portion 720 of FIG. 7, according to some embodiments of the present disclosure. FIG. 8 illustrates three portions 810, 812, and 814 of the etch stop layer 410. The upper portion 810, i.e., the portion that includes the top surface 512, has the highest concentration of oxygen and, correspondingly, the lowest concentration of carbon. In some embodiments, the upper portion 810, or another upper region of the etch stop layer 410 (e.g., a top-most crystal layer, the upper surface, the uppermost 5 angstroms (Å), the uppermost 10 Å, the uppermost 20 Å, the uppermost 50 Å, etc.) has an atomic percentage of oxygen of at least 30%, at least 40%, at least 45%, approximately 50%, between 40 and 50%, between 45 and 50%, or within some other range.

The middle portion 812 has a lower concentration of oxygen compared to the upper portions 810, and it has a correspondingly higher concentration of carbon. The lowest portion 814 has the lowest concentration of oxygen and, correspondingly, the highest concentration of carbon. In this example, the lowest portion 814 does not include any oxygen atoms 510. In other embodiments, the lowest portion 814 may include some oxygen atoms 510, e.g., a trace amount of oxygen. For example, the lowest portion 814, or another lower region of the etch stop layer 410 (e.g., a lower-most crystal layer, the lower surface, the lowermost 5 angstroms (Å), the lowermost 10 Å, the lowermost 20 Å, the lowermost 50 Å, etc.) may include an atomic percentage of oxygen of less than 5%, less than 1%, less than 0.1%, less than 0.01%, etc.

### Example Devices

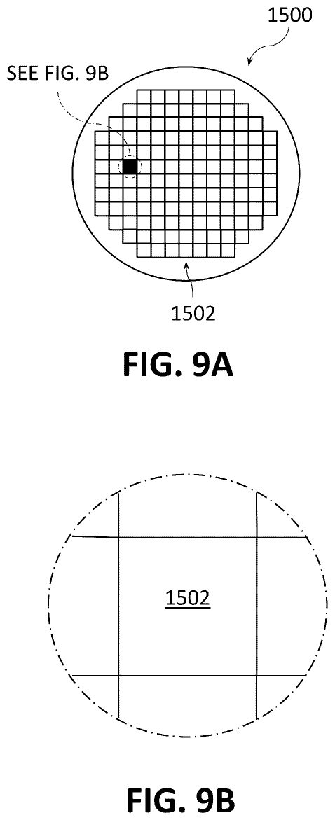

The circuit devices with one or more metal layers with at least one graduated etch stop layer disclosed herein may be included in any suitable electronic device. FIGS. 9-12 illustrate various examples of apparatuses that may include the one or more transistors disclosed herein, which may have been fabricated using the processes disclosed herein.

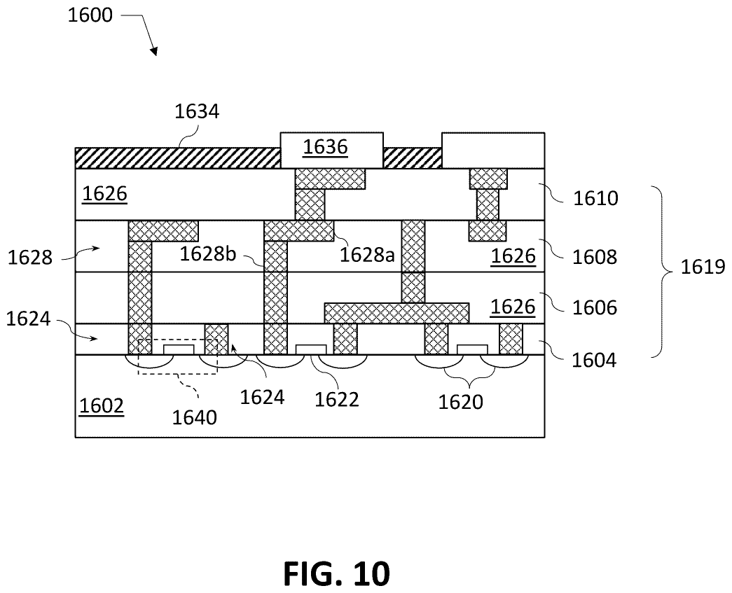

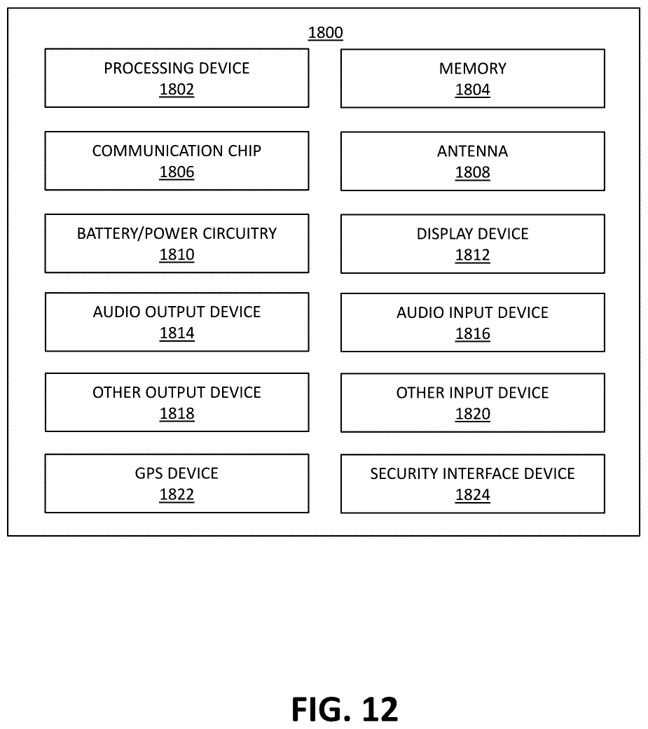

FIGS. 9A and 9B are top views of a wafer and dies that include one or more IC structures including one or more metal layers with at least one graduated etch stop layer in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 3-10, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 10, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 12) or other logic that is configured to store information in the memory devices or execute instructions stored in the memory array.

FIG. 10 is a cross-sectional side view of an IC device 1600 that may include one or more metal layers with at least one graduated etch stop layer in accordance with any of the embodiments disclosed herein. The IC device 1600 may be formed on a substrate 1602 (e.g., the wafer 1500 of FIG. 9A) and may be included in a die (e.g., the die 1502 of FIG. 9B). The substrate 1602 may be any substrate as described herein. The substrate 1602 may be part of a singulated die (e.g., the dies 1502 of FIG. 9B) or a wafer (e.g., the wafer 1500 of FIG. 9A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more metal layers with at least one graduated etch stop layer at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 10 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 10). Although a particular number of interconnect layers 1606-1610 is depicted in FIG. 10, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 10. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 10. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

FIG. 13 is a cross-sectional side view of an IC device assembly 1700 that may include components having or being associated with (e.g., being electrically connected by means of) one or more metal layers with at least one graduated etch stop layer in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

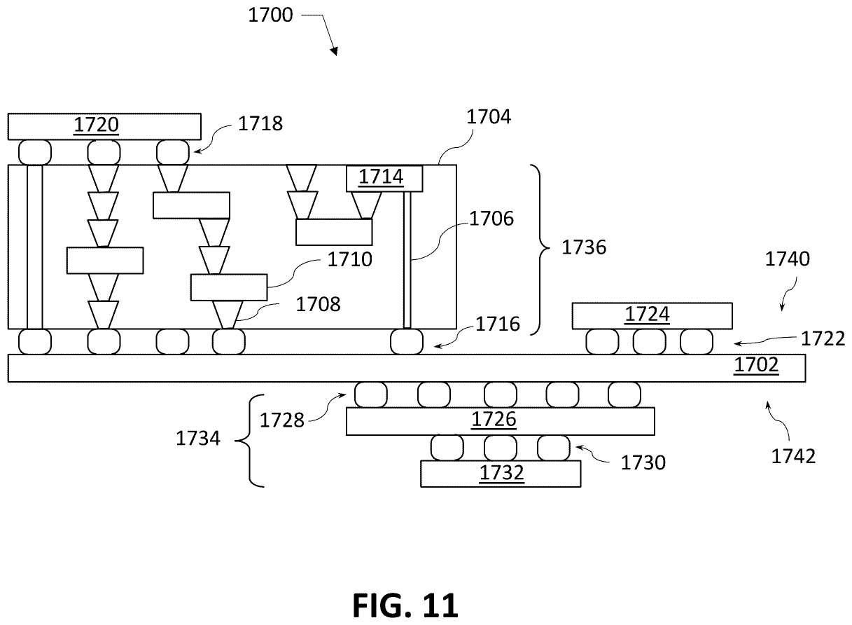

The IC device assembly 1700 illustrated in FIG. 11 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 11), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 11, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 9B), an IC device (e.g., the IC device 1600 of FIG. 10), or any other suitable component. In some embodiments, the IC package 1720 may include one or more metal layers with at least one graduated etch stop layer, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 11, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 11 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 12 is a block diagram of an example computing device 1800 that may include one or more metal layers with at least one graduated etch stop layer in accordance with any of the embodiments disclosed herein. For example, any suitable ones of the components of the computing device 1800 may include a die (e.g., the die 1502 (FIG. 9B)) having one or more metal layers with at least one graduated etch stop layer. Any one or more of the components of the computing device 1800 may include, or be included in, an IC device 1600 (FIG. 10). Any one or more of the components of the computing device 1800 may include, or be included in, an IC device assembly 1700 (FIG. 11).

A number of components are illustrated in FIG. 12 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 12, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides an integrated circuit (IC) device including a first layer including a dielectric material and a conductive structure; and a second layer over the first layer, where the second layer includes silicon, carbon, and oxygen, the second layer has a first concentration of oxygen in a first portion of the second layer and a second concentration of oxygen in a second portion of the second layer, the first portion is farther from the first layer than the second portion, and the first concentration is greater than the second concentration.

Example 2 provides the IC device of example 1, where a via extends through the second layer, and the via is in contact with the conductive structure of the first layer.

Example 3 provides the IC device of example 1 or 2, further including a third layer over the second layer, the second layer including the dielectric material.

Example 4 provides the IC device of any preceding example, where the second layer is an etch stop layer.

Example 5 provides the IC device of any preceding example, where the second layer has a third portion between the first portion and the second portion, the third portion has a third concentration of oxygen, and the third concentration is between the first concentration and the third concentration.

Example 6 provides the IC device of any preceding example, where the second layer has a lower concentration of carbon in the first portion than in the second portion.

Example 7 provides the IC device of any preceding example, where the first layer and the second layer are in a metallization stack of the IC device.

Example 8 provides the IC device of example 7, the IC device further including a device layer with a plurality of transistors, where the first layer is between the device layer and the second layer.

Example 9 provides the IC device of any preceding example, where the second layer has a dielectric constant that is less than 5.3.

Example 10 provides the IC device of any preceding example, where an atomic percentage of oxygen in the first portion is at least 40%.

Example 11 provides an integrated circuit (IC) device including a device layer including a plurality of transistors; and a plurality of metallization layers over the device layer, where one of the metallization layers includes a graduated layer, the graduated layer has a first surface and a second surface, the first surface is farther from the device layer than the second surface, and the graduated layer has a greater concentration of a dopant at the first surface than at the second surface.

Example 12 provides the IC device of example 11, where the metallization layer is one of the first eight metal layers over the device layer.

Example 13 provides the IC device of example 11, where the metallization layer is one of the first five metal layers over the device layer.

Example 14 provides the IC device of any of examples 11-13, where the dopant is oxygen.

Example 15 provides the IC device of example 14, where an atomic percentage of oxygen at the first surface is at least 40%.

Example 16 provides the IC device of example 14 or 15, the graduated layer further includes silicon and oxygen.

Example 17 provides the IC device of any of examples 11-16, where the one of the metallization layers further includes a metal line, and the graduated layer is over the metal line.

Example 18 provides the IC device of any of examples 11-17, where the one of the metallization layers further includes a via, the via extending through the graduated layer.

Example 19 provides a method including depositing a layer of carbon and silicon over at least one metallization layer of an integrated circuit device; doping the deposited layer of carbon and silicon with oxygen to provide a doped layer, where an upper portion of the doped layer has a greater amount of oxygen than a lower portion of the doped layer; and forming at least one additional metallization layer over the doped layer.

Example 20 provides the method of example 19, further including forming a plasma within a deposition chamber, where the depositing the layer of carbon and silicon and the doping the deposited layer of carbon and silicon with oxygen are performed in the plasma.

Example 21 provides an IC package that includes an IC die, including one or more of the IC devices according to any one of the preceding examples. The IC package may also include a further component, coupled to the IC die.

Example 22 provides the IC package according to example 21, where the further component is one of a package substrate, a flexible substrate, or an interposer.

Example 23 provides the IC package according to examples 21 or 22, where the further component is coupled to the IC die via one or more first level interconnects.

Example 24 provides the IC package according to example 23, where the one or more first level interconnects include one or more solder bumps, solder posts, or bond wires.

Example 25 provides a computing device that includes a circuit board; and an IC die coupled to the circuit board, where the IC die includes one or more of the transistor/IC devices according to any one of the preceding examples (e.g., transistor/IC devices according to any one of examples 1-20), and/or the IC die is included in the IC package according to any one of the preceding examples (e.g., the IC package according to any one of examples 21-24).

Example 26 provides the computing device according to example 25, where the computing device is a wearable computing device (e.g., a smart watch) or hand-held computing device (e.g., a mobile phone).

Example 27 provides the computing device according to examples 25 or 26, where the computing device is a server processor.

Example 28 provides the computing device according to examples 25 or 26, where the computing device is a motherboard.

Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. An integrated circuit (IC) device comprising:
a first layer comprising a dielectric material and a conductive structure; and
a second layer over the first layer, wherein the second layer comprises silicon, carbon, and oxygen, the second layer has a first concentration of oxygen in a first portion of the second layer and a second concentration of oxygen in a second portion of the second layer, the first portion is farther from the first layer than the second portion, and the first concentration is greater than the second concentration.

2. The IC device of claim 1, wherein a via extends through the second layer, and the via is in contact with the conductive structure of the first layer.

3. The IC device of claim 1, further comprising a third layer over the second layer, the second layer comprising the dielectric material.

4. The IC device of claim 1, wherein the second layer is an etch stop layer.

5. The IC device of claim 1, wherein the second layer has a third portion between the first portion and the second portion, the third portion has a third concentration of oxygen, and the third concentration is between the first concentration and the third concentration.

6. The IC device of claim 1, wherein the second layer has a lower concentration of carbon in the first portion than in the second portion.

7. The IC device of claim 1, wherein the first layer and the second layer are in a metallization stack of the IC device.

8. The IC device of claim 7, the IC device further comprising a device layer with a plurality of transistors, wherein the first layer is between the device layer and the second layer.

9. The IC device of claim 1, wherein the second layer has a dielectric constant that is less than 5.3.

10. The IC device of claim 1, wherein an atomic percentage of oxygen in the first portion is at least 40%.

11. An integrated circuit (IC) device comprising:
a device layer comprising a plurality of transistors; and
a plurality of metallization layers over the device layer, wherein one of the metallization layers comprises a graduated layer, the graduated layer has a first surface and a second surface, the first surface is farther from the device layer than the second surface, and the graduated layer has a greater concentration of a dopant at the first surface than at the second surface.

12. The IC device of claim 11, wherein the metallization layer is one of the first eight metal layers over the device layer.

13. The IC device of claim 11, wherein the metallization layer is one of the first five metal layers over the device layer.

14. The IC device of claim 11, wherein the dopant is oxygen.

15. The IC device of claim 14, wherein an atomic percentage of oxygen at the first surface is at least 40%.

16. The IC device of claim 14, the graduated layer further comprises silicon and oxygen.

17. The IC device of claim 11, wherein the one of the metallization layers further comprises a metal line, and the graduated layer is over the metal line.

18. The IC device of claim 11, wherein the one of the metallization layers further comprises a via, the via extending through the graduated layer.

19. A method comprising:
depositing a layer of carbon and silicon over at least one metallization layer of an integrated circuit device;
doping the deposited layer of carbon and silicon with oxygen to provide a doped layer, wherein an upper portion of the doped layer has a greater amount of oxygen than a lower portion of the doped layer; and
forming at least one additional metallization layer over the doped layer.

20. The method of claim 19, further comprising:
forming a plasma within a deposition chamber, wherein the depositing the layer of carbon and silicon and the doping the deposited layer of carbon and silicon with oxygen are performed in the plasma.
